(19) United States
(12) Patent Application Publication
(10) Pub. No.: US 2014/0041719 A1
(43) Pub. Date: Feb. 13, 2014

(54) Manufacture of a Solar Module

(71) Applicants: Michael Haag, Rodenbach (DE); Ruediger Kellmann, Mainz (DE); Markus Schmidt, Seibersbach (DE)

(72) Inventors: Michael Haag, Rodenbach (DE); Ruediger Kellmann, Mainz (DE); Markus Schmidt, Seibersbach (DE)

(73) Assignee: INTERNATIONAL BUSINESS MACHINES CORPORATION, Armonk, NY (US)

(21) Appl. No.: 13/572,964

(22) Filed: Aug. 13, 2012

(51) Int. Cl. H01L 31/0232; H01L 31/18

(52) U.S. Cl. 136/256; 438/72; 257/E31.127

(57) ABSTRACT

A photovoltaic cell with reduced shading and series resistance for increased efficiency. A contact grid containing a set of optical structures is embedded into a substrate. An array of electrical contacts is aligned and in electrical communication with the optical structures and provides electrical communication between the active layer and the substrate.

### BACKGROUND

1. Technical Field

The present invention relates to photovoltaic cells. More specifically, the invention relates to a method and product for optimizing optical properties of one or more interconnects in a photovoltaic cell.

2. Description of the Prior Art

The art of photovoltaic cells addresses the conversion of radiation into electrical energy. Much research has been conducted to maximize the efficiency of a photovoltaic cell. One limitation in maximizing efficiency is the lost energy due to shading effects caused by a contact grid of the photovoltaic cell being opaque to solar radiation. The contact grid however, must be embedded in a conductive layer of a photovoltaic cell to collect the current of electrons that flows over the surface of the cell. Because the internal resistance of a typical solar cell is relatively high, the contact grid of the solar cell is placed across the surface of a cell to minimize the distance an electron has to travel on the surface of a cell, thus minimizing the ohmic loss due to internal resistance. Accordingly, a balance must be compromised between the effects of shading and the losses due to electrical resistance.

### SUMMARY OF THE INVENTION

This invention comprises a method for manufacturing a contact grid embedded in a photovoltaic cell, and a photovoltaic cell produced by the process.

In one aspect, a method is provided to produce a photovoltaic cell. A contact grid is pre-formed into a first substrate of a photovoltaic cell. More specifically, a first optical structure is embedded into the first substrate. A first electrical contact is aligned in communication with the first optical structure on a first side of the first substrate, with the first side of an active layer secured to the first side of the substrate. More specifically, the first electrical contact is soldered from the substrate to the first side of the active layer such that the first electrical contact is in electrical communication with the active layer.

In another aspect, a photovoltaic cell is provided. A first substrate is provided having a first embedded contact grid. More specifically, a first optical structure is embedded into the first substrate with a first electrical contact in communication with the first optical structure on a first side of the first substrate. An active layer is further provided having a first side and a second side. The first side of the active layer is secured to the first substrate. More specifically, the first electrical contact of the first substrate is soldered to and in electrical communication with the first side of the active layer.

In yet another aspect, a photovoltaic cell is produced by the method as described. A contact grid is pre-formed into a first substrate of a photovoltaic cell. More specifically, a first optical structure is embedded into the first substrate. A first electrical contact is aligned in communication with the optical structure on a first side of the first substrate. A first side of an active layer is secured to a first side of the substrate. More specifically, the first set of electrical contacts from the substrate is soldered to the first side of the active layer such that the first electrical contact is in electrical communication with the active layer.

### BRIEF DESCRIPTION OF THE DRAWINGS

The drawings referenced herein form a part of the specification. Features shown in the drawings are meant as illustrative of only some embodiments of the invention, and not of all embodiments of the invention unless otherwise explicitly indicated. Implications to the contrary are otherwise not to be made.

FIG. 1 depicts a flow chart illustrating a process for creating a photovoltaic cell.

FIGS. 2A, 2B, and 2C are illustrative drawings illustrating a process for creating a contact grid for a photovoltaic cell.

FIG. 3 is an illustrative drawing depicting one embodiment for a photovoltaic cell.

### DETAILED DESCRIPTION

It will be readily understood that the components of the present invention, as generally described and illustrated in the Figures herein, may be arranged and designed in a wide variety of different configurations. Thus, the following detailed description of the embodiments of the apparatus, system, and method of the present invention, as presented in the Figures, is not intended to limit the scope of the invention, as claimed, but is merely representative of selected embodiments of the invention.

Reference throughout this specification to “a select embodiment,” “one embodiment,” or “an embodiment” means that a particular feature, structure, or characteristic described in connection with the embodiment is included in at least one embodiment of the present invention. Thus, appearances of the phrases “a select embodiment,” “in one embodiment,” or “in an embodiment” in various places throughout this specification are not necessarily referring to the same embodiment.

Furthermore, the described features, structures, or characteristics may be combined in any suitable manner in one or more embodiments. In the following description, numerous specific details are provided, such as examples of sensors, detectors, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

The illustrated embodiments of the invention will be best understood by reference to the drawings, wherein like parts are designated by like numerals throughout. The following description is intended only by way of example, and simply illustrates certain selected embodiments of devices, systems, and processes that are consistent with the invention as claimed herein.

In the following description of the embodiments, reference is made to the accompanying drawings that form a part hereof, and which shows by way of illustration the specific embodiment in which the invention may be practiced. It is to be understood that other embodiments may be utilized because structural changes may be made without departing form the scope of the present invention.

A solar cell is a semiconductor device that converts radiation energy into electrical energy. Reference herein to a diode, photovoltaic cell, and active layer are considered synonymous with a solar cell and the definition thereof.

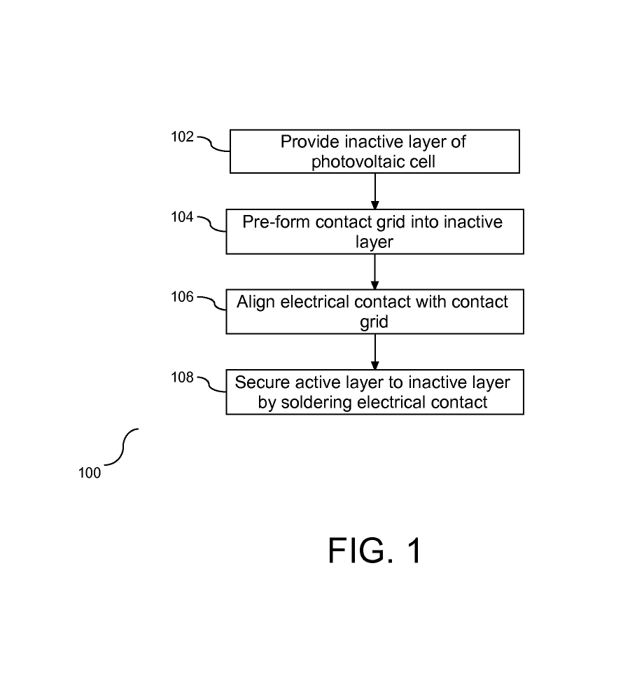

FIG. 1 is a flow chart (100) depicting a method for creating a solar cell. A first substrate is provided for the solar cell (102). The first substrate is transparent to optical radiation and in one embodiment is comprised of glass. A contact grid is pre-formed in the first substrate (104). More specifically, the contact grid is a set of at least one optical structure that is embedded into the first substrate (104). The contact grid is embedded such that at least one optical structure is electrically communicative with a first surface of the first substrate. In one embodiment, the first substrate is comprised of glass or an alternate transparent material and the contact grid is embedded and plated into a polymer film that is applied to the first substrate. In another embodiment, the contact grid is embedded such that at least one optical structure forms part of the first surface of the first substrate. In another embodiment, the contact grid is embedded such that at least one optical structure protrudes from the inactive layer. Accordingly, the first substrate is provided with a contact grid having an embedded optical structure.

Solder material in the form of an electrical contact is aligned with the contact grid (106). The electrical contact is aligned such that there is at least one corresponding electrical contact placed in electrical communication with the optical structure on the first surface of the first substrate. In one embodiment, there are multiple optical structures in the first substrate and the solder material is aligned such that there is a set of at least one electrical contact for every optical structure of the contact grid in electrical communication with each optical structure. Once aligned, an active layer e.g. a solar cell, is secured to the inactive layer by soldering the electrical contacts to both the first side of the first substrate and a first side of the active layer (108). In one embodiment, the second side of the active layer is similarly soldered to a first side of a second substrate having an embedded contact grid through the use of a second set of at least one electrical contact. In this embodiment, the active layer is sandwiched between two similarly structured substrates. In another embodiment, the active layer and the first and second substrates of the solar cell are manufactured separately prior to soldering. Accordingly, a contact grid is embedded in a substrate and soldered to an active layer such that the substrate and the active layer are in electrical communication.

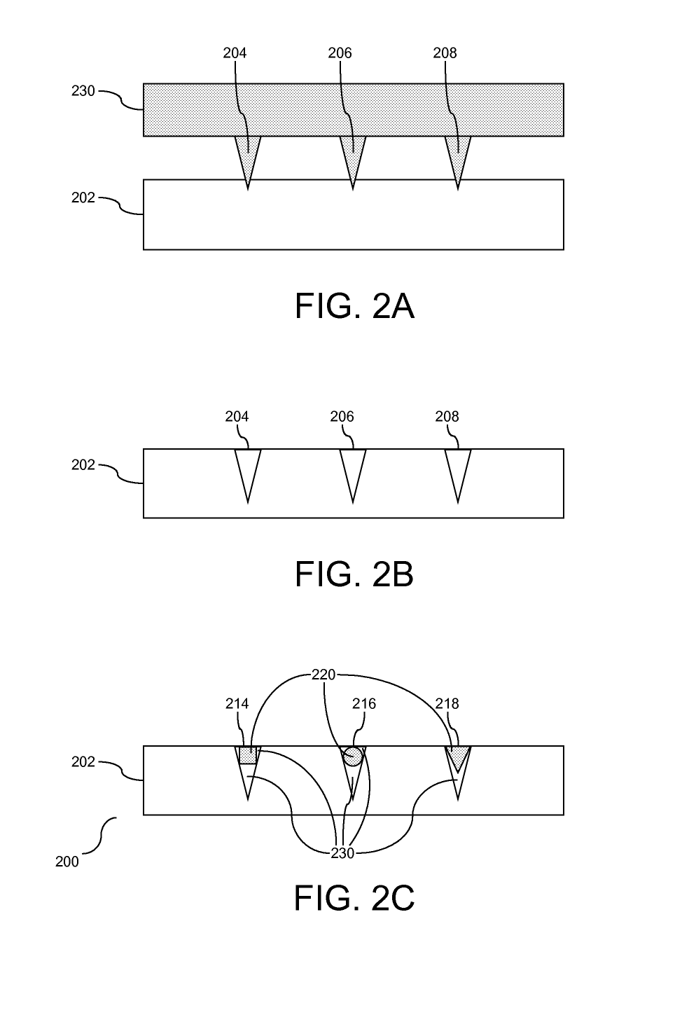

FIGS. 2A, 2B and 2C are drawings (200) illustrating an aspect of embedding a contact grid (220) into a substrate (202). The substrate (202) is an optically transparent substrate having a set of optical structures (204), (206), and (208). For purposes of illustration, three optical structures (204), (206), and (208), comprise the set of optical structures however any integer number of optical structures more than zero can be utilized. In one embodiment, the set of optical structures are triangular in shape as depicted in optical structures (204), (206), and (208). In another embodiment, the set of optical structures (204), (206), and (208), are triangles with a high aspect ratio to minimize effects of radiation shading such that the triangles have a greater height than base width. The contact grid is further comprised of an electrically conductive material. In one embodiment, the contact grid is embedded into a first side of the substrate (202) as shown in FIG. 2A by hot embossing a triangle stamp into the inactive layer forming indentations and a combination of electrolysis and electroplating. Similarly, in one embodiment, a pre-fabricated triangular conducting structure (230) is hot embedded into the substrate (202) by stamping. FIG. 2B illustrates the optical structures (204), (206), and (208), fully embedded in the substrate (202). Accordingly, the contact grid and optical structures are pre-formed and embossed within the inactive layer.

FIG. 2C depicts one embodiment of the substrate (202) with the contact grid (220) embedded therewith. As shown, the conducting structure is not limited to a triangular conducting structure. Rather, the conducting structure may be in the form of a square or parallelogram (214), circular or spherical (216), or triangular in shape (218), or an alternative geometric shape size to fit within the optical structure. In one embodiment, the substrate (202) with an embedded contact grid can be manufactured separately from the active layer. As shown herein, a thin gap (230) is provided between the preformed optical structures (204), (206), and (208) and the contact grid (220), chosen in a shape not commensurate with the preformed optical structure. In one embodiment, the thin gap (230) has a material of lower refractive index than the inactive layer material (202). Similarly, in one embodiment, the thin gap (230) provides for total internal reflection at the interface between the inactive layer (202) and the optical structures (204), (206), and (208). An element contained within the gap is chosen from a group of materials with lower refractive index than the material comprising the inactive layer (202), and in one embodiment is comprised of air. Accordingly, the contact grid (220) can be formed within the optical structure in varying shapes and spacing.

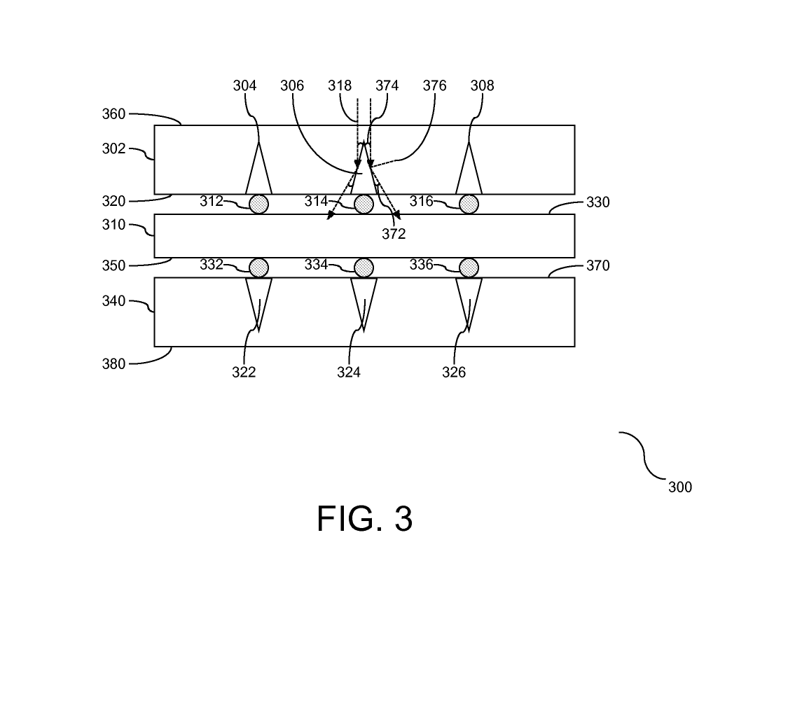

FIG. 3 is a drawing (300) illustrating one embodiment of a solar cell. A first substrate (302) is shown with a first embedded contact grid with a first set of optical structures (304), (306), and (308). A first set of electrical contacts, (312), (314), and (316) are in electrical communication with the embedded contact grid. More specifically, optical structure (304) is in communication with electrical contact (312), optical structure (306) is in communication with electrical contact (314), and optical structure (308) is in communication with electrical contact (316). As shown, solder is provided as an electrical connection between the first substrate and the active layer (310). In one embodiment, solder is applied to or transferred to the first substrate adjacent to each optical structure and forms a solder ball. Each of the solder balls (312), (314), and (316) support the electrical connection of the first substrate to a first side of the active layer (330). For purposes of illustration, three electrical contacts (312), (314), and (316), comprise the first set of electrical contacts however any number of electrical contacts can be utilized. In one embodiment of the invention, the electrical contacts are lead free in that they do not contain a detectable amount of lead. In a further embodiment, a dielectric material fills the space in between the electrical contacts (312), (314), and (316) for electrical insulation and mechanical stability. At minimum, one electrical contact in the first set is placed in electrical communication with one optical structure of the contact grid on the first side of the first substrate (302) as well as placed in electrical communication with the first side of the active layer (330).

As shown, the optical structures (304), (306), and (308) are triangular in shape, in one embodiment, with each structure having two legs. Specifically, optical structure (304) has legs (304a) and (304b), optical structure (306) has legs (306a) and (306b), and optical structure (308) has legs (308a) and (308b). In one embodiment, the legs of the optical structure are comprised of a metallic material, which functions to both direct radiation to the active layer (310) and to support contact with the solder. Specifically, the material of the legs provides ohmic contact between the solder ball and the active layer. The first substrate (302) receives light and the optical structure(s) direct the radiation associated with the received light into the active layer (310). In one embodiment of the invention, the optical structure comprises electrical wiring that functions to reflect incoming radiation such that radiation (318) that contacts optical structure (304), (306), or (308), is directed into the active layer (310).

A second substrate (340) is shown having an embedded second contact grid with a second set of optical structures (322), (324), and (326). A second set of electrical contacts (332), (334), and (336), are aligned in electrical communication with the embedded second contact grid. More specifically, optical structure (322) is in communication with electrical contact (332), optical structure (324) is in communication with electrical contact (334), and optical structure (326) is in electrical communication with electrical contact (336). As shown, the optical structures (322), (324), and (326) are triangular in shape, in one embodiment, with each structure having two legs. Specifically, optical structure (322) has legs (322a) and (322b), optical structure (324) has legs (324a) and (324b), and optical structure (326) has legs (326a) and (326b).

As shown, solder is provided as an electrical connection between the second substrate and the second side of the active layer (350). For purposes of illustration, three electrical contacts (332), (334), and (336), comprise the second set of electrical contacts however any number of electrical contacts can be utilized. At minimum, one electrical contact in the second set is placed in electrical communication with one optical structure of the second contact grid on the first side of the second substrate (370) as well as placed in electrical communication with the second side of the active layer (350). The second side of the active layer (350) is soldered to the first side of the second inactive layer (370). Accordingly, the active layer (310) is sandwiched between two substrates, (302) and (340) respectively. In one embodiment, ohmic contact between the first set of solder balls (312), (314), and (316), and the first side of the active layer (330) as well as the second set of solder balls (332), (334), and (336), and the second side of the active layer (350) is supported through a laser firing process.

In one embodiment, an antireflection coating is applied to the second surface of the first inactive layer (360) and/or the second surface of the second inactive layer (380) in order to minimize reflected radiation and maximize the transparency of the first substrate (302). In another embodiment, a reflective mirror is applied to a second side of the second substrate (380) oppositely disposed to the first side of the second substrate (370). The reflective mirror functions to reflect radiation into the active layer (310) that would otherwise have passed through the photovoltaic cell.

Due to the shape of the optical structures, radiation (318) contacting the contact grid is directed into the active layer. According to Snell's Law, a widely accepted principle of physics, light reflected into a like medium is reflected at the same angle of incidence θ₂ (372) as received θ₁ (374) with respect to the normal (376) of the reflecting object. The triangular shape of the first set of optical structures (304), (306), and (308), and the second set of optical structures (322), (324), and (326) creates slanted surfaces. These slanted surfaces direct light away from the electrical contact of the optical structures and into the active layer (310). Accordingly, the contact grid directs any light contacting the contact grid into the active layer.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed.

Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

### Alternative Embodiment

It will be appreciated that, although specific embodiments of the invention have been described herein for purposes of illustration, various modifications may be made without departing from the spirit and scope of the invention. Accordingly, the scope of protection of this invention is limited only by the following claims and their equivalents.

We claim:

1. A method comprising:
pre-forming a contact grid into a first substrate of a photovoltaic cell, including embedding a first optical structure into the first substrate;
aligning a first electrical contact in communication with the optical structure on a first side of the first substrate; and
securing a first side of an active layer to the first side of the first substrate, including soldering the first set of at least one electrical contact from the first substrate to the first side of the active layer such that the first electrical contact is in electrical communication with the active layer.

2. The method of claim 1, wherein the first optical structure directs radiation received by the first substrate into the active layer.

3. The method of claim 1, wherein the first optical structure is a triangular structure.

4. The method of claim 1, further comprising securing a second side of the active layer to the first side of a second substrate having a second embedded contact grid, including aligning a second electrical contact in communication with a second optical structure embedded on a first side of the second substrate.

5. The method of claim 1, further comprising the first substrate having a first side oppositely disposed from a second side, the first side to receive radiation and the second side to secure to a first side of the active layer.

6. The method of claim 1, further comprising the first optical structure directing the received radiation to the first side of the active layer.

7. The method of claim 1, wherein the first substrate is manufactured separate from the active layer.

8. The method of claim 1, further comprising coating a substantial surface of the active layer with a dielectric filler material.

9. The method of claim 1, further comprising coating a substantial surface of the first substrate with an antireflection coating.

10. The method of claim 1, further comprising applying a light reflective mirror in communication with the first substrate for reflecting radiation into the active layer.

11. The method of claim 1, wherein the electrical contact is lead free.

12. The method of claim 1, further comprising hot embossing and plating the contact grid into a polymer film.

13. The method of claim 1, wherein the first optical structure is preformed and transferred to the first substrate, including a gap formed within the optical structure provided for total internal reflection.

14. A photo-voltaic cell comprising:
a first substrate having a first embedded contact grid, including a first optical structure embedded into the first substrate and a first electrical contact in communication with the first optical structure on a first side of the first substrate;
an active layer having a first side and a second side, the first side of the active layer secured to the first substrate, including the first electrical contact of the first substrate soldered to and in electrical communication with the first side of the active layer.

15. The photo-voltaic cell of claim 14, further comprising the first substrate having a second side oppositely disposed from the first side of the first substrate, the second side to receive radiation, and the first contact grid to direct the received radiation into the active layer.

16. The photo-voltaic cell of claim 14, further comprising, a second substrate having a second embedded contact grid, including a second optical structure embedded into the second substrate and a second electrical contact in communication with the second optical structure on a first side of the second substrate, the second side of the active layer secured to the first side of the second substrate, including the second electrical contact of the second substrate soldered to and in electrical communication with the second side of the active layer.

17. The photo-voltaic cell of claim 16, further comprising a second side of the second substrate to receive radiation and the second contact grid to direct the received radiation to the active layer.

18. The photo-voltaic cell of claim 14, wherein the first optical structure is a triangular structure.

19. The photo-voltaic cell of claim 14, wherein the optical structure reduces loss associated with shading.

20. The photo-voltaic cell of claim 14, further comprising a dielectric filler material to coat a substantial surface of the active layer.

21. The photo-voltaic cell of claim 14, further comprising an anti-reflection layer to substantially coat a surface of the active layer to increase the absorption of received radiation in the active layer.

22. The photo-voltaic cell of claim 14, further comprising the first contact grid embedded and plated into a polymer film.

23. A photo-voltaic cell, prepared by the process comprising the steps of:
pre-forming a contact grid into a first substrate of a photovoltaic cell, including embedding a first optical structure into the first substrate;
aligning a first electrical contact in communication with the optical structure on a first side of the first substrate; and
securing a first side of an active layer manufactured separately from the substrate, to the first side of the substrate, including soldering the first set of at least one electrical contact from the substrate to the first side of the active layer such that the first electrical contact is in electrical communication with the active layer.
